(19) United States
(12) Patent Application Publication
(10) Pub. No.: US 2016/0179991 A1
(43) Pub. Date: Jun. 23, 2016

(54) MICROGRID TROUBLESHOOTING METHOD

(71) Applicant: NATIONAL CHUNG SHAN INSTITUTE OF SCIENCE AND TECHNOLOGY, Longtan Township (TW)

(72) Inventors: SHI-LIN CHEN, LONGTAN TOWNSHIP (TW); KENG-YU LIEN, LONGTAN TOWNSHIP (TW); KUO-KUANG JEN, LONGTAN TOWNSHIP (TW); CHEN-HO HUANG, LONGTAN TOWNSHIP (TW)

(21) Appl. No.: 14/572,918

(22) Filed: Dec. 17, 2014

(51) Int. Cl. G06F 17/50

(52) U.S. Cl. CPC G06F 17/5009

(57) ABSTRACT

A microgrid troubleshooting method entails, connecting a first trouble simulating unit between a utility electricity and an AC load, wherein an AC end of a second trouble simulating unit connects with the AC load, and a DC end of the second trouble simulating unit connects with a solar power generating unit, an energy-storing unit, a fuel cell unit, and a DC load; switching the second trouble simulating unit to a short-circuit state, measuring a microgrid earth potential rise, short-circuit current of the solar power generating unit, and short-circuit current of the energy-storing unit, and checking whether the microgrid is damaged; and switching the first trouble simulating unit to a short-circuit state, measuring a microgrid earth potential rise, and checking whether the microgrid is damaged. The method is effective in simulating troubles with the microgrid, measuring the microgrid's short-circuit current, and testing whether the microgrid's protection mechanism is functioning well.

### FIELD OF TECHNOLOGY

The present invention relates to electronic test technology, and more particularly, to a microgrid troubleshooting method for use with a renewable energy-based microgrid.

### BACKGROUND

A microgrid consists of multiple renewable energy-based power generation systems. Although the renewable energy-based power generation system technology is sophisticated nowadays, the construction of a reliable microgrid system hinges on plenty of related techniques. A conventional DC microgrid mainly consists of distributed power sources, including: a solar power generating system (operating in conjunction with a maximum power point tracker (MPPT)), fuel cells, energy storing apparatuses (provided mostly in the form of lithium iron batteries), and inverters. To ensure that each part and component of the microgrid is functioning well, it is necessary to design a troubleshooting process flow method for evaluating whether the system comes with sufficient protective mechanisms, by checking the carrying capability of the path of a trouble-related current, measuring the voltage level of contact between the system's earth potential rise (an increase in ground potential) and AC/DC load, and assessing the short-circuit current characteristics of the solar panel, the energy storing apparatuses, the inverters, and the DC system, so as to construct perfect microgrid operation mechanisms.

The troubleshooting process flow must take account of the risks that can compromise the insulation of the power supply apparatuses of the system, the safety of the worker conducting a test, and the synchrony of measurement. Important considerations given to the design process include: the troubleshooting process causes an abnormal increase in the anode voltage of the DC system, causes the system's zero potential to shift from the neutral point to the trouble point and distort the initial distribution of paired earth potentials, compromises the insulation of the apparatuses of the DC system to thereby produce the second trouble point, and thus causes a short-circuit trouble between the anode and the cathode. The aforesaid abnormal increase in the anode voltage of the DC system is likely to cause electric shock to the workers. Furthermore, a trouble with the single-phase grounding of the AC system boosts the earth potential and thus causes damage to light-current apparatuses like a nearby communication apparatus and causes electric shock to the workers. With the microgrid comprising therein a plurality of distributed power sources, energy storing batteries, and fuel cells, the system's voltage and current are in a transient state during a trouble-stricken period of time, and thus measurement instruments and meters have to be operating synchronously.

### SUMMARY

In view of the drawbacks of the prior art, the present invention provides a microgrid troubleshooting method for use in simulating troubles confronted by a microgrid, measuring short-circuit current at each part and component of the microgrid, and testing whether a protection mechanism of the microgrid is functioning well.

The present invention provides a microgrid troubleshooting method. The microgrid comprises a utility electricity, an AC load, a solar power generating unit, an energy-storing unit, a fuel cell unit, and a DC load. The method comprises the steps of: providing a first trouble simulating unit and a second trouble simulating unit, the first trouble simulating unit being connected between the utility electricity and the AC load, the second trouble simulating unit having an AC end and a DC end, wherein the AC end of the second trouble simulating unit connects with the AC load, wherein the DC end of the second trouble simulating unit connects with the solar power generating unit, the energy-storing unit, the fuel cell unit and the DC load; switching the second trouble simulating unit to a short-circuit state to thereby use a measurement instrument to measure earth potential rise of the microgrid, the short-circuit current of the solar power generating unit, and the short-circuit current of the energy-storing unit, and check whether each part and component of the microgrid is damaged; and switching the first trouble simulating unit to a short-circuit state to thereby use the measurement instrument to measure the earth potential rise of the microgrid and check whether each part and component of the microgrid is damaged.

In an embodiment, the solar power generating unit has a maximum power point tracker (MPPT).

In an embodiment, the energy-storing unit is a lithium iron battery, a lead-acid battery, or any rechargeable battery.

In an embodiment, the three-phase switch is an air circuit breaker (ACB).

In an embodiment, the microgrid comprises an inverter.

In an embodiment, the first trouble simulating unit has a transformer, a three-phase switch and a three-phase variable resistor, whereas the second trouble simulating unit has a DC-AC converter, a three-phase switch and a three-phase variable resistor, wherein the first trouble simulating unit and the second trouble simulating unit are for use in simulating troubles with constituent elements of the microgrid and a short-circuit thereof so as to test the short-circuit current at each part and component of the microgrid and test whether the protection mechanisms of the microgrid are functioning well.

The present invention applies to a renewable energy-based microgrid operating at 48 V_{dc}and 380V_{dc}. The present invention renders it feasible to test the strength and waveform of the short-circuit current at each part and component of a microgrid and verify whether a conventional circuit breaker disposed in the microgrid is capable of quarantining the troubles. The present invention is further characterized in that: while the short-circuit current test is underway, it is also practicable to check whether the path of the short-circuit current causes any anomaly to a related apparatus, such as a screw or a terminal plate. Therefore, the present invention is effective in checking and testing the overall security and performance indicators of a renewable energy-based DC microgrid.

The above overview and the following description and drawings are intended to further explain the effects, means and measures taken to achieve the predetermined objectives of the present invention. The other objectives and advantages of the present invention are illustrated with the description and drawings below.

### BRIEF DESCRIPTION

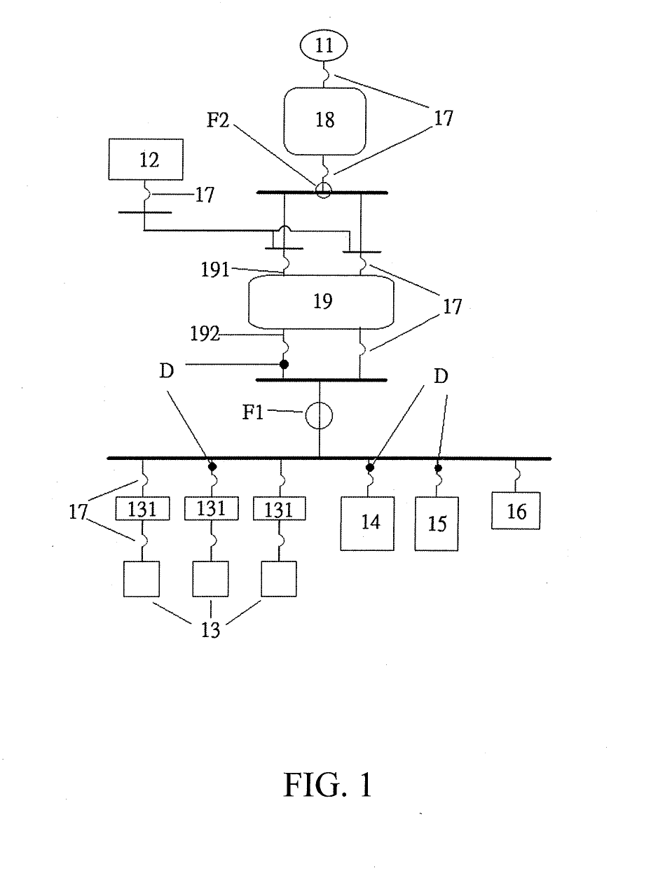

FIG. 1 is a schematic view of the framework of a troubleshooting system according to an embodiment of the present invention;

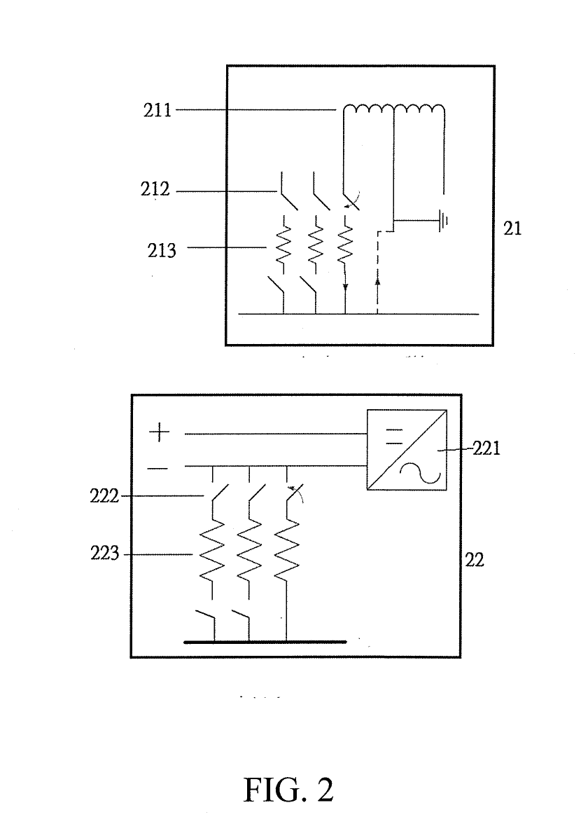

FIG. 2 is a schematic view of the structure of a first trouble simulating unit and a second trouble unit according to an embodiment of the present invention;

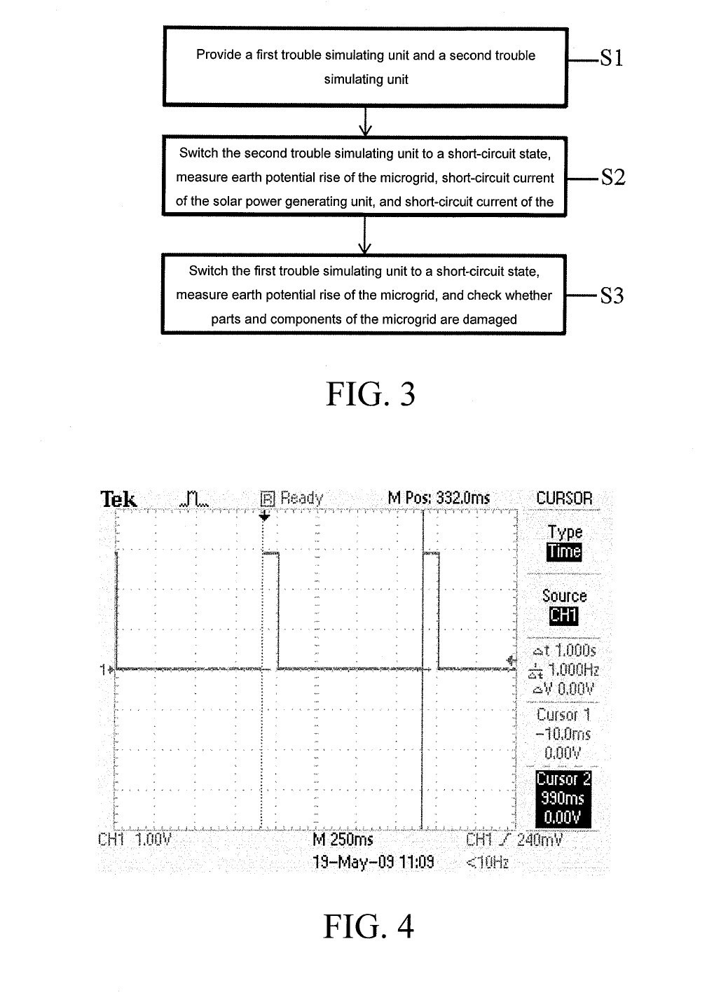

FIG. 3 is a flowchart of a microgrid troubleshooting method according to an embodiment of the present invention;

FIG. 4 is a diagram of the waveform of PPS outputted from a GPS according to an embodiment of the present invention; and

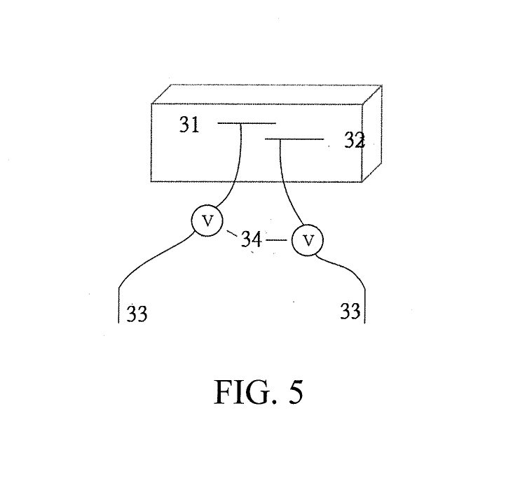

FIG. 5 is a schematic view of earth potential rise measurement according to an embodiment of the present invention.

### DETAILED DESCRIPTION

The implementation of the present invention is described with a specific embodiment below. By referring to the disclosure contained in this specification, persons skilled in the art can easily gain insight into the other advantages and effects of the present invention.

Referring to FIG. 1, there is shown a schematic view of the framework of a troubleshooting system according to an embodiment of the present invention. As shown in the diagram, the troubleshooting system comprises a utility electricity 11, an AC load 12, a solar power generating unit 13, an energy-storing unit 14, a fuel cell unit 15, a DC load 16, a plurality of protection units 17, a first trouble simulating unit 18, and a second trouble simulating unit 19. The first trouble simulating unit 18 is connected between the utility electricity 11 and the AC load 12. The second trouble simulating unit 19 has an AC end 191 and a DC end 192. The AC end 191 of the second trouble simulating unit 19 connects with the AC load 12. The DC end 192 of the second trouble simulating unit 19 connects with the solar power generating unit 13, the energy-storing unit 14, the fuel cell unit 15, and the DC load 16. The first trouble simulating unit 18 and the second trouble simulating unit 19 simulate a short circuit resulting from a trouble with a constituent component of the microgrid so as to test short-circuit current at each part and component of the microgrid and test whether the protection units 17 or any other protection mechanism is functioning well. In the course of its operation, the present invention is characterized in that a measurement instrument straddles measurement point D between the solar power generating unit 13 and the second trouble simulating unit 19 or that the measurement instrument connects with measurement point D between the energy-storing unit 14 and the fuel cell unit 15 in order to measure the earth potential rise of the microgrid and short-circuit current at each part and component of the microgrid during the troubleshooting process. The solar power generating unit 13 has a MPPT control unit 131. The protection units 17 are fused or fuseless switches. The measurement instrument is a voltmeter, a current meter, or a three-phase power quality analyzer. The microgrid comprises an inverter (not shown) disposed between the DC side (solar power generating unit, energy-storing unit, fuel cell unit, and DC load) and the AC side (utility electricity, AC load) and adapted to convert the current on the DC side into an alternate current or convert the current on the AC side into a direct current. The energy-storing unit is a lithium iron battery, a lead-acid battery, or any rechargeable battery.

Referring to FIG. 2, there is shown a schematic view of the structure of a first trouble simulating unit and a second trouble unit according to an embodiment of the present invention. The first trouble simulating unit 21 has a transformer 211, a three-phase switch 212 and a three-phase variable resistor 213. The second trouble simulating unit 22 has a DC-AC converter 221, a three-phase switch 222 and a three-phase variable resistor 223. The internal resistance and electrical conduction of the first trouble simulating unit 21 and the second trouble unit 22 are changed by the three-phase switches 212, 222 and the three-phase variable resistors 213, 223, respectively, so as to simulate a trouble-related short circuit which occurs to an AC side component or a DC side component of the microgrid and thus carry out the troubleshooting of the microgrid. The DC-AC converter 221 functions as an inverter. The three-phase switches 212, 222 are air circuit breakers (ACB).

Referring to FIG. 3, there is shown a flowchart of a microgrid troubleshooting method according to an embodiment of the present invention. As shown in the diagram, the method comprises the steps of: providing a first trouble simulating unit and a second trouble simulating unit (S1), with the first trouble simulating unit connected between the utility electricity and the AC load, and the second trouble simulating unit having the AC end and the DC end, wherein the AC end of the second trouble simulating unit connects with the AC load, and the DC end of the second trouble simulating unit connects with a solar power generating unit, an energy-storing unit, a fuel cell unit, and a DC load; switching the second trouble simulating unit to a short-circuit state, measuring earth potential rise of the microgrid, short-circuit current of the solar power generating unit, and short-circuit current of the energy-storing unit, and checking whether each part and component of the microgrid is damaged (S2); switching the first trouble simulating unit to a short-circuit state, measuring the earth potential rise of the microgrid, and checking whether each part and component of the microgrid is damaged (S3).

The microgrid troubleshooting method of the present invention has two trouble scenario test modes. Referring to FIG. 1, the first trouble scenario assumes that, during a period of time when the microgrid uses the solar power generating unit 13 or the utility electricity 11 to supply power, trouble F1 occurs to the DC side, whereas the first trouble scenario involves developing a short circuit with the second trouble simulating unit 19 to therefore test the strength of the short-circuit current at the solar power generating unit 13, the energy-storing unit 14, or an inverter and test whether the protection units 17 are operating correctly. In the first trouble scenario, items measured include the earth potential rise on the DC side, the short-circuit current characteristics of MPPT, the short-circuit current characteristics of an inverter, and the short-circuit current characteristics of the energy-storing unit 14 (such as lithium iron batteries). The second trouble scenario assumes that, during a period of time when power is supplied by the fuel cell unit 15, a trouble happens to the microgrid at F2. In the second trouble scenario, a short circuit is developed by the first trouble simulating unit 18. In the second trouble scenario, the earth potential rise of the microgrid is measured. Regarding the actual application of the present invention, since the trouble-related current of the short circuit of the AC system is high, it is advantageous to carry out the DC short-circuit test of the first trouble scenario first to therefore measure the N-phase (neutral point) paired earth potentials of the AC side of the microgrid and the waveforms of the MPPT, the inverters, and the energy-storing unit 14 of the DC side, and eventually conduct the test of second trouble scenario.

Regarding the actual application of the present invention, although measurement apparatuses undergo calibration of time before conducting a test, they are not free of errors in timing when there are multiple measurement apparatuses. The errors are likely to cause difficulty in aligning the level of a time axis during a waveform analysis process and therefore lead to wrong judgments; therefore, the present invention is characterized in that calibration of time is performed with a global positioning system (GPS), wherein the GPS sends a PPS (one pulse per second) signal to one of the phases of each measurement instrument such that the signal align the voltage waveform and the current waveform so as to facilitate the waveform analysis performed after the test. In an embodiment of the present invention, a PPS waveform generated from the GPS is shown in FIG. 4. In this embodiment, although the pulse duration is 100 ms/pulse, users may vary the pulse duration as needed, and thus the present invention is not limited thereto.

Referring to FIG. 4 and FIG. 5, there is shown in FIG. 5 a schematic view of earth potential rise measurement according to an embodiment of the present invention. In practical application of the present invention, trouble-related current passing an earth grid is likely to cause the earth potential to rise, and therefore it is necessary to test paired earth potential difference of N-phase line 31 (disposed at the first trouble simulating unit 18 or an otherwise connected transformer (not shown)) on the AC side to avoid burning out a nearby electrical appliance. Moreover, paired earth potential difference of a DC system can also compromise the equipment insulation inside the DC system. Therefore, in the DC side system of the microgrid, an over-voltage protection device (OVPD) is grounded and connected to positive and negative poles to thereby finalize the grounding of the microgrid. To ensure safety, first, the resistances of the three-phase variable resistors 213, 223 in the first trouble simulating unit 18 and the second trouble simulating unit 19 are tuned to the maximum, such that the trouble-related current is at the least, so as to infer the subsequent paired earth potential difference of the trouble-related current, requiring no larger than 65 V_{ac} or 150 V_{dc}. Therefore, the upper limit of the trouble-related current is tuned down from 300 A, and the paired earth potentials of N-phase line 31 and the DC negative electrode 32 on the AC side of this system are measured. To measure the earth potentials, it is necessary to extend the N-phase line 31 and the DC negative electrode 32 outward by 20 m with grounding lines, respectively, peg an electrode bar (not shown) into the earth to serve as a reference electrode 33, measure the earth potential rise with a voltage measurement instrument 34, and extend the voltage measurement instrument 34 outward by 20 m. The voltage measurement instrument 34 is a voltmeter or a three-phase power quality analyzer.

The aforesaid embodiments are illustrative of the features and advantages of the present invention, but should not be interpreted as restrictive of the scope of the substantive technical contents of the present invention. Hence, modifications and replacements can be made to the aforesaid embodiments by persons skilled in the art without departing from the spirit and scope of the present invention should fall within the scope of the present invention. Accordingly, the legal protection for the present invention should be defined by the appended claims.

What is claimed is:

1. A microgrid troubleshooting method, wherein the microgrid comprises a utility electricity, an AC load, a solar power generating unit, an energy-storing unit, a fuel cell unit, and a DC load, the method comprising the steps of:
providing a first trouble simulating unit and a second trouble simulating unit, with the first trouble simulating unit connected between the utility electricity and the AC load, the second trouble simulating unit having an AC end and a DC end, wherein the AC end of the second trouble simulating unit connects with the AC load, wherein the DC end of the second trouble simulating unit connects with the solar power generating unit, the energy-storing unit, the fuel cell unit, and the DC load;
switching the second trouble simulating unit to a short-circuit state, using a measurement instrument to measure earth potential rise of the microgrid, short-circuit current of the solar power generating unit, and short-circuit current of the energy-storing unit, and checking whether each part and component of the microgrid is damaged; and
switching the first trouble simulating unit to a short-circuit state, using the measurement instrument to measure the earth potential rise of the microgrid, and checking whether each part and component of the microgrid is damaged.

2. The microgrid troubleshooting method of claim 1, wherein the solar power generating unit has a maximum power point tracker (MPPT).

3. The microgrid troubleshooting method of claim 1, wherein the energy-storing unit is one of a lithium iron battery, a lead-acid battery, and any rechargeable battery.

4. The microgrid troubleshooting method of claim 1, wherein the first trouble simulating unit has a transformer, a three-phase switch, and a three-phase variable resistor.

5. The microgrid troubleshooting method of claim 1, wherein the second trouble simulating unit has a DC-AC converter, a three-phase switch, and a three-phase variable resistor.

6. The microgrid troubleshooting method of claim 4, wherein the three-phase switch is an air circuit breaker (ACB).

7. The microgrid troubleshooting method of claim 5, wherein the three-phase switch is an air circuit breaker (ACB).

8. The microgrid troubleshooting method of claim 1, wherein the measurement instrument is one of a voltmeter, a current meter, and a three-phase power quality analyzer.

9. The microgrid troubleshooting method of claim 1, wherein the microgrid comprises an inverter.
